(19) United States
(12) Patent Application Publication
(10) Pub. No.: US 2003/0159728 A1
(43) Pub. Date: Aug. 28, 2003

(54) Device for protecting a photovoltaic module against hot spots and photovoltaic module equipped with same

(76) Inventor: Jean-Paul Berry, Ramonville St Agne (FR)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/257,369

(22) PCT Filed: Apr. 17, 2001
(86) PCT No.: PCT/FR01/01172

(51) Int. Cl. H01L 31/00

(52) U.S. Cl. 136/256

(57) ABSTRACT

An anti-hot spot device for at least one photovoltaic module (10) including:

a photovoltaic module shunt diode (20),

means (36, 40) for detecting at least one operating characteristic of the photovoltaic module, and

means (22, 34) for isolating the photovoltaic module (10) from the chain in response to an abnormal operating characteristic being detected.

### TECHNICAL FIELD

The present invention relates to a device intended to protect and preserve the photovoltaic cells of a photovoltaic module. In particular it makes it possible to avoid an abnormal operation of the cells which might cause them to overheat and therefore to age more quickly.

The device is therefore termed an “anti-hot spot” device.

The invention finds applications in the manufacture of photovoltaic generators.

### THE PRIOR ART

Photovoltaic generators, and in particular high-power photovoltaic generators are generally divided into several sub-generators.

The sub-generators comprise one or more photovoltaic modules, associated in a chain, and are themselves associated so as to increase the overall power of the generator. Each sub-generator may then be equipped with a regulator allowing it to be slaved to its peak power point.

The purpose of subdividing the generators into sub-generators individually slaved to their peak power point is to restrict imbalances that might appear, or that might initially exist, between different photovoltaic modules of the generator.

Imbalances exist not only between the modules, or chains of modules, but also between different individual photovoltaic cells composing the modules. Operating imbalances may arise from a non-homogeneous illumination of the photovoltaic cells, from differences between the temperatures of the cells, from their ageing, from bad contacts, or again from the surface condition of the cells. Imbalances may also arise from a dispersion of the initial physical characteristics of the associated cells. They are then accentuated by a non-homogeneous illumination or operating temperature.

Operating imbalances, when they are significant, may cause the polarity of a number of the photovoltaic cells in the modules to be reversed. These cells then operate as a receiver rather than as a generator of current, and absorb electrical energy instead of supplying it.

To be more exact, a cell whose polarity is reversed absorbs the electrical energy of all the cells with which it is connected in series. It therefore receives significant electrical power, likely to damage it. Moreover, the power absorbed by the cell is taken away from the overall power delivered by the generator.

To restrict the power absorbed by a defective cell, a known method is to associate a shunt diode with units formed of a certain number of cells in series.

A generator equipped with shunt diodes is shown in the appended FIG. 1.

The generator in FIG. 1 includes a plurality of photovoltaic modules 10, identical to each other, connected in series to form a chain of modules. The chain of modules is terminated by output terminals 12, 14 to which an electric charge may be connected.

The modules are for example modules with 50 W of power, formed by putting 36 photovoltaic cells in series. In the figure, the individual photovoltaic cells are not shown in the interests of clarity.

As is shown in FIG. 1, a shunt diode 20 is connected in parallel to each module 10 respectively.

In a device in accordance with FIG. 1, when an individual cell of one of the photovoltaic modules finds its polarity reversed, it absorbs not the electrical power supplied by all the cells in series between the output terminals 12, 14, but only the power supplied by the cells of the photovoltaic module of which it is part. Thus, in the example chosen, a defective cell can therefore withstand only a maximum 50 watts of power when it is operating as a receiver.

The current supplied by the other modules of the chain passes through the shunt diode 20 associated with the module containing the defective cell. An additional advantage of this is that the generator is only cut off from the power supplied by the module containing the defective cell.

In normal operation the shunt diodes are reverse polarised. However the shunt diode associated with a module containing a defective cell, in other words a module at the terminals of which the voltage is collapsing, lets through the current impressed by the other modules of the chain, operating normally.

Despite reducing some negative effects, the use of shunt diodes does not make it possible to obtain generators whose reliability can be guaranteed over a long period of time.

Indeed a certain number of additional problems, identified by the inventor, and disclosed below, are instrumental in reducing the life span and the manufacture of photovoltaic generators.

When a photovoltaic cell operates as a receiver, further to its polarity being reversed, it absorbs, as previously indicated, all or part of the energy supplied by the other cells in series with it.

Thus, even when shunt diodes are provided, the cell operating as a receiver sees its temperature increase under the effect of a thermal dissipation of the power received from the other cells of the module of which it is part. In this way the so-called hot spot is formed.

The increase in temperature then increases the imbalance between this cell and the other cells remaining at normal temperature.

The mechanics of this leads to the hot spot being locked in, in other words a lock-in which prevents the cell from returning to a normal operating mode, as a generator, even when the cause of the initial imbalance has disappeared.

The hot spot lock-in may possibly disappear when the photovoltaic generator ceases to be illuminated, in such a way that the current supplied to the locked-in cell disappears and that it may be possible for it to cool down.

However, accelerated ageing may be noted in the cells when they are locked in as a hot spot. The physical characteristics of these cells evolve differently in fact from cells operating normally. The consequence of this is to increase the dispersions of characteristics and the imbalances between cells, and therefore to promote the hot spot lock-in mechanism.

The premature ageing of some cells also multiplies the number of hot spot lock-ins and reduces the life span and the reliability of the whole generator.

### DISCLOSURE OF THE INVENTION

The aim of the present invention is to propose a photovoltaic generator which does not have the aforementioned problems.

Another aim is to propose a device, called an anti-hot spot device, which aims to reduce the premature ageing of some cells by preventing them from locking-in as a hot spot.

One final aim is to propose a straightforward and cost-effective device which allows the life span, the reliability and the manufacture of photovoltaic generators to be increased.

In fulfilment of these aims, the exact subject of the invention is an anti-hot spot device for at least one photovoltaic module connected in a chain of photovoltaic modules. The device includes:

a photovoltaic module shunt diode,

means for detecting at least one operating characteristic of the photovoltaic module, and

means for preventing a current from circulating in the module in response to an abnormal operating characteristic being detected.

By preventing a current from circulating in the module it is possible, particularly, to prevent a current from passing through a reversed cell of the module.

By abnormal operating characteristic is understood a characteristic which lies outside a range of tolerance, for example when its values crosses, positively or negatively, a threshold value.

In the invention device, when a module has a defective cell, the shunt diode is still used to shunt a current produced by the other modules in the chain, operating normally.

Moreover, in accordance with the invention, the module which has a defective cell, for example a cell whose polarity has been reversed as a result of an operating imbalance, is isolated from the chain.

Electrical isolation of the module with a defective cell makes it possible to prevent the other cells of the module, which are operating normally, from supplying a current to the defective cell, which would operate as a receiver.

The temperature of the defective cell is not therefore maintained nor is it increased by thermal dissipation. The cell is thus able to recover or retain a temperature equal to that of the adjoining cells. In other terms, the electrical isolation of the module concerned makes it possible to prevent the defective cell from locking-in as a hot spot.

This allows a balance between the cell in question and the other cells of the module to be restored more quickly. Balance is here taken to be a dispersion of characteristics which is sufficiently small to allow all the photovoltaic cells to operate normally as a generator. This does not however pre-suppose that the characteristics are absolutely identical from one cell to the other.

Furthermore, isolating the module makes it possible to prevent the premature ageing of the defective cell, linked to hot spot lock-in.

According to one particular embodiment of the device, the means for isolating the photovoltaic module may comprise:

an on/off power switch connected in series with the photovoltaic module in the chain of modules, between the shunt diode terminals, and

threshold on/off switch control means, controlled by the operating characteristic detection means, for opening the on/off switch in response to the threshold being crossed.

Using threshold control means makes it possible not to cause the module to be isolated in respect of slight operating imbalances but only when a dysfunction such as a reversal of polarity occurs in respect of a cell.

Furthermore, it may be noted that putting the on/off switch in series with the photovoltaic module, between the terminals of the shunt diode, makes it possible to prevent this diode, when it is in the on-state, from short-circuiting the isolated module.

The aforementioned threshold may be crossed by higher or lower values according to the operating characteristic considered.

By way of example, when the operating characteristic detected is a voltage at the module terminals, or a value linked to this voltage, the on/off switch may be caused to open by a voltage value below a threshold voltage corresponding to a lower limit of a module operation considered as normal.

In another example, in the event of the temperature of the cells being detected, the on/off switch could be caused to open in response to a photovoltaic cell temperature being detected which exceeds a maximum set temperature.

According to another advantageous particularity of the invention, the on/off switch control means may comprise means for periodically causing the on/off switch to close, independently of the operating characteristic.

This characteristic makes it possible to maintain the module isolation state for as short a time as possible. Indeed, if the cause of the dysfunction has disappeared, closing the on/off switch makes it possible to reconnect the module and thus recover the full power of the chain.

If, on the other hand, the cell imbalance persists, each periodic closure of the on/off switch is followed respectively by another opening of the on/off switch, caused by an operating characteristic equal to a defective operation being detected.

The means for causing the on/off switch periodically to close are comparable to a delayed automatic “re-set” system that makes it possible to prevent the whole generator from being disconnected, or an operator from having to intervene in any way.

In a particular embodiment of the delayed automatic re-set (monostable) means they may comprise a capacitor, connected in parallel to the photovoltaic module and kept in a charge state by a resistance when the voltage at the module terminals is above a threshold. A discharge diode, in series with the capacitor, is then provided to discharge the capacitor when the shunt diode becomes conductive.

In this embodiment, the capacitor, associated with the discharge diode, represents, via its charge state, an operating characteristic of the module. Indeed, the voltage at the capacitor terminals is approximately equal to the module voltage in normal operation.

In association with the capacitor, the on/off power switch control means may comprise a threshold switch. This is connected to the capacitor terminals so as to switch as a function of the voltage existing between the capacitor terminals, in other words as a function of its charge. When the voltage at the capacitor terminals passes below a threshold (by discharge through the diode) the on/off control switch opens (off-state). The on/off power switch gate is no longer polarised by the on/off control switch and discharges through a gate-drain resistance. The on/off power switch opens (off-state). The capacitor is then recharged by a resistance. After a given time there is re-set.

The on/off power switch may comprise one or more MOSFET transistors (field effect transistors of the metal oxide semiconductor type). In this case, the threshold switch makes it possible to operate the on/off power switch either in an on-state, or in an off-state, so as to isolate or not to isolate the module.

The invention also relates to a photovoltaic generator including a plurality of photovoltaic modules connected in series, in which each photovoltaic module is equipped with an anti-hot spot device as described.

Other characteristics and advantages of the invention will emerge from the following description, with reference to the appended drawings. This description is given purely by way of example and in no way restrictively.

### BRIEF DESCRIPTION OF THE FIGURES

FIG. 1, already described, is a diagrammatic representation of a branch of a photovoltaic generator of a known type, equipped with a chain of several photovoltaic modules.

FIG. 2 is a diagrammatic representation on a larger scale of a photovoltaic module equipped with an anti-hot spot device, in accordance with the invention, and connected in a branch of a partially shown generator.

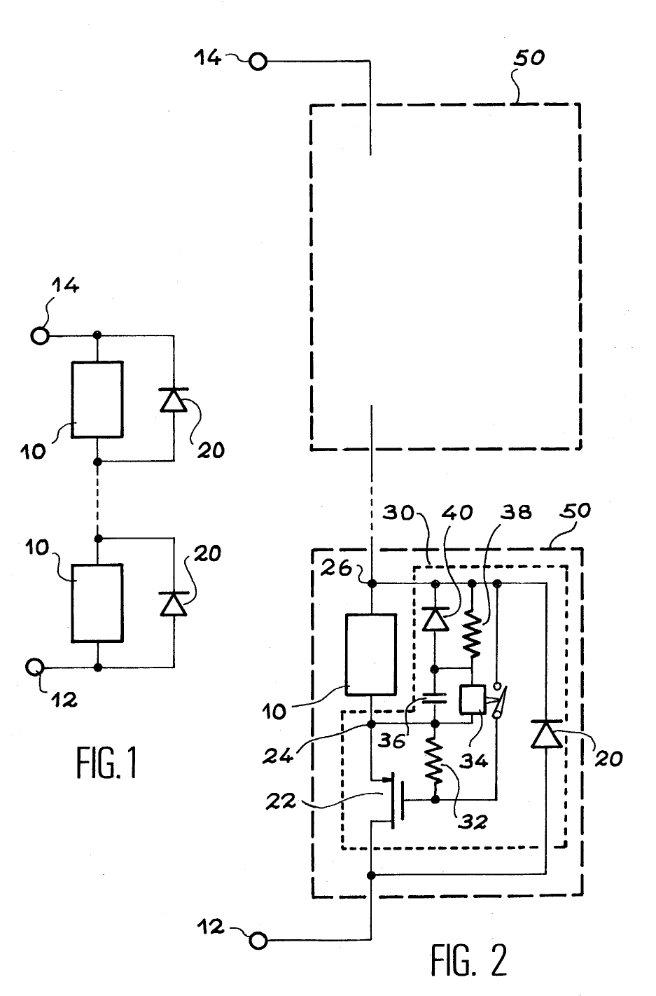

### DETAILED DESCRIPTION OF EMBODIMENTS OF THE INVENTION

FIG. 2 shows a photovoltaic module 10 connected in series with other modules between a first terminal 12 and second terminal 14 of a photovoltaic generator to form a chain of modules. In the example in the figure, the terminal 12 is a negative terminal of the generators and the terminal 14 is a positive terminal. The module 10, of a type known per se, comprises preferably a plurality of photovoltaic cells connected in series. It is connected in a branch of the generator, in series with an n-type MOSFET transistor 22 the source of which is connected to a first terminal 24 of the module and the drain of which is connected either to a terminal of a previous module in the chain, or, in the example in the figure, to the first terminal 12 of the generator. The MOSFET transistor, used here as an on/off power switch, is part of an anti-hot spot device 30, connected furthermore to a second terminal 26 of the module 10.

Also to be seen is a shunt diode 20 the anode of which is connected to the drain of the transistor 22 and the cathode of which is connected to the second terminal 26 of the module. The shunt diode 20 allows an electric current produced by other modules of the chain to pass through when the module being considered, equipped with the diode, is isolated from the chain.

The gate of the MOSFET transistor 22 is connected to its source, and therefore to the first terminal 24 of the module, by means of a first polarisation resistance 32. The gate is further connected to the second terminal 26 of the module, via a threshold switch 34 which is closed (on-state) in a normal operating mode.

In this operating mode, the MOSFET transistor 22 is conductive and connects the module 10 to the chain, by putting it in series with the other modules. Its gate is polarised to the voltage of the module by the closed on/off control switch (on-state).

To this end, a transistor is preferably chosen which is capable of conducting a strong current and which has a voltage drop small enough to be negligible relative to the nominal module voltage.

The threshold switch 34 is controlled by the voltage at the terminals of a capacitor 36. The capacitor is connected to the terminals of the module by means of a second resistance 38 and a diode 40. More exactly, the second resistance and the diode are connected in parallel to each other, and connect one of the plates of the capacitor 36 to the second terminal 26 of the module. The other plate of the capacitor is directly connected to the first terminal 24 of the module 10. The diode 40 is further termed “discharge diode” in the remainder of the text.

When the module 10 is operating normally, in other word when all the module cells are behaving as a generator, the diode 40 is polarised in the off-state sense. The capacitor 36, charged by means of the second resistance makes it possible to apply to the input of the threshold switch 34 sufficient voltage for the latter to remain in the closed position (on-state). However, as previously indicated, when the threshold switch 34 is in the closed position (on-state), the MOSFET transistor 22 operates in an on-state, and is comparable to a closed on/off switch.

When the voltage of the module 10 collapses further to the shunt diode 20 being made conductive from current being injected by the external chain, the discharge diode 40 is polarised directly and discharges the capacitor 36.

The voltage drop of the capacitor causes the threshold switch 34 to open (off-state) . The gate of the MOSFET 22 is then discharged through the resistance 32. The MOSFET opens (off-state).

It then behaves like an open on/off switch and isolates the module 10 being considered from the other modules of the chain.

After it is discharged, the capacitor 36 does not remain in a discharged state. It is recharged at the terminals of the isolated module 10, by means of the second resistance 38.

As soon as the voltage at the terminals of the capacitor once again exceeds the threshold of the switch 34, the latter closes (on-state) and the MOSFET transistor 22 is put once again into the on-state.

If the operating fault affecting the module being considered 10, or at the very least one of its cells, has disappeared, the capacitor 36 remains charged and the module is kept connected in the chain. If on the other hand, the fault persists, the capacitor 36 is discharged once more through the discharge diode 40 and the module is again isolated by the MOSFET transistor 22 being put in the off-state.

The unit formed by the capacitor 36, the discharge diode 40 and the second resistance 38, thus constitutes a monostable circuit which sets the time during which the module is isolated.

As previously explained, the temporary isolation of a module makes it possible to prevent hot spot lock-ins and therefore preserves the cells concerned from premature ageing.

In the example described here, the photoelectric generator includes a chain of photoelectric modules 10 each associated with an anti-hot spot device 30. The unit formed by a module and an anti-hot spot device is identified with the reference 50. In the interests of simplification, only two units 50 of the chain in FIG. 2 are shown.

It should also be pointed out that an anti-hot spot device may be associated with a variable number of cells or photovoltaic modules.

Furthermore, it should be pointed out that the generator may comprise several chains of modules in parallel.

1. An anti-hot spot device for at least one photovoltaic module (10) connected in a chain of photovoltaic modules, including:
a photovoltaic module shunt diode (20),
means (36, 40) for detecting at least one operating characteristic of the photovoltaic module, and
means (22, 34) for preventing a current from circulating in the module (10) in response to an abnormal operating characteristic being detected.

2. A device according to claim 1, wherein the means for preventing a current from circulating in the photovoltaic module comprise:
an on/off power switch (22) connected in series with the photovoltaic module (10) in the chain of modules, between the terminals of the shunt diode (20), and
means (34) for controlling the on/off switch, controlled by the operating characteristic detection means, for opening the on/off switch in response to a threshold being crossed by the characteristic.

3. A device according to claim 2, additionally comprising means (38) for periodically causing the on/off switch to close, independently of the operating characteristic.

4. A device according to claim 3, wherein the means (38) for periodically causing the on/off power switch to close are part of a monostable circuit (36, 38, 40).

5. A device according to claim 1 or 2, wherein the operating characteristic is a voltage at the terminals of the photovoltaic module.

6. A device according to claim 5, wherein the means for detecting the operating characteristic comprise a capacitor (36), connected in parallel to the photovoltaic module and kept in a charge state when the voltage at the module terminals is above a conduction threshold of the shunt diode (20), and a discharge diode (40), in series with the capacitor (36), so as to discharge the capacitor when the shunt diode (20) becomes conductive.

7. A device according to claim 2, wherein the on/off power switch control means comprise a threshold switch (34), connected to the terminals of the capacitor (36).

8. A device according to claim 2, wherein the on/off power switch (22) comprises a MOSFET transistor.

9. A photovoltaic generator including a plurality of photovoltaic modules (10) connected in series, in which each photovoltaic module is equipped with an anti-hot spot device (30) in accordance with any one of the previous claims.

10. A photovoltaic module including a plurality of photovoltaic cells and an anti-hot spot device in accordance with any one of the claims 1 to 8.
